(19) United States
(12) Patent Application Publication
(10) Pub. No.: US 2022/0074681 A1
(43) Pub. Date: Mar. 10, 2022

(54) HEAT SINK AND THERMAL DISSIPATION STRUCTURE

(71) Applicants: Inventec (Pudong) Technology Corporation, Shanghai (CN); INVENTEC CORPORATION, Taipei City (TW)

(72) Inventors: Kai-Yang TUNG, TAIPEI CITY (TW); Hung-Ju CHEN, TAIPEI CITY (TW)

(21) Appl. No.: 17/030,401

(22) Filed: Sep. 24, 2020

(30) Foreign Application Priority Data
Sep. 8, 2020 (CN) 202010931836.9

(51) Int. Cl. F28F 3/06

(52) U.S. Cl. CPC F28F 3/06

(57) ABSTRACT

A heat sink includes a bottom plate, a liquid barrier structure and a plurality of heat conducting fins. The liquid barrier structure is located on the periphery of the bottom plate. The heat conducting fins are arranged on the bottom plate. The heat conducting fins are located in the liquid barrier structure.

### RELATED APPLICATIONS

This application claims priority to China Application Serial Number 202010931836.9, filed Sep. 8, 2020, which are herein incorporated by reference.

### BACKGROUND

### Field of Invention

The present invention relates to a heat sink and a thermal dissipation structure.

### Description of Related Art

For conventional heat sink with directional fin design, liquid droplets used for cooling can only be dropped on the grooves between fins of heat sinks such that the liquid droplets can only flow forward or backward in a single direction in the grooves. This makes the heat exchange effect of the liquid droplets for cooling limited, resulting in poor overall temperature uniformity of the heat sink and reducing the heat dissipation effect.

Therefore, how to provide a solution for the above mentioned problem is one of the subjects to be solved for the industry.

### SUMMARY

To achieve the above object, an aspect of the present invention is related to a heat sink used to solve the mentioned thermal dissipation problem caused by the bad flowing of coolant.

One aspect of the present invention relates to a heat sink.

According to one embodiments of the present invention, a heat sink includes a bottom plate, a liquid barrier structure and a plurality of heat conducting fins. The liquid barrier structure is located on the periphery of the bottom plate. The heat conducting fins are arranged on the bottom plate. The heat conducting fins are located in the liquid barrier structure.

In one or more embodiments of the present invention, the heat conducting fins include a plurality of columnar heat conducting fins.

In some embodiments of the present invention, a projection of each of the columnar heat conducting fins on the bottom plate is a circle.

In some embodiments of the present invention, the columnar heat conducting fins are arranged in a plurality of straight rows in the liquid barrier structure. The straight rows extend in a first direction. The straight rows are arranged in a second direction.

In some embodiments of the present invention, the first direction is perpendicular to the second direction.

In some embodiments of the present invention, the columnar heat conducting fins are arranged at equal intervals in the first direction.

In some embodiments of the present invention, the straight rows include a first straight row and a second straight row that are immediately-adjacent two of the straight rows. A plurality of first columnar heat conducting fins of the columnar heat conducting fins is arranged in the first straight row. A plurality of second columnar heat conducting fins of the columnar heat conducting fins is arranged in the second straight row. Any one of the first columnar heat conducting fins is not aligned with any of the second columnar heat conducting fins in the second direction.

In one or more embodiments of the present invention, the mentioned heat sink further includes a locking structure and an isolation wall. The locking structure is arranged on the bottom plate. The isolation wall is located on the bottom plate. The isolation wall is arranged between the locking structure and the heat conducting fins.

In some embodiments of the present invention, the locking structure is adjacent to the periphery of the bottom plate. The isolation wall is connected to the liquid barrier structure. The isolation wall and the liquid barrier structure jointly surround the locking structure.

One aspect of the present invention relates to a thermal dissipation structure.

According to one embodiments of the present invention, a thermal dissipation structure includes a heat sink and a coolant source. The heat sink is arranged on a heat source. The heat sink includes a bottom plate, a liquid barrier structure and a plurality of columnar heat conducting fins. The liquid barrier structure is located on a periphery of the bottom plate. The columnar heat conducting fins are arranged on the bottom plate. The columnar heat conducting fins are located in the liquid barrier structure. The coolant source is arranged above the heat sink to drip a coolant on the columnar heat conducting fins. The coolant source drips the coolant toward the liquid barrier structure.

In summary, the present invention provides a heat sink having a liquid barrier structure and heat conducting fins. The heat conducting fins are, for example, columnar fins, which can reduce the flow resistance and improve the fluidity of the coolant droplets received by the heat conducting fins. Such a heat sink can be applied to a thermal dissipation structure.

It is to be understood that both the foregoing general description and the following detailed description are by examples, and are intended to provide further explanation of the invention as claimed.

### BRIEF DESCRIPTION OF THE DRAWINGS

In order to make the above and other objects, features, advantages, and embodiments of the present invention more comprehensible, the description of the drawings is as follows:

FIG. 1 illustrates a perspective view of a heat sink located on a heat source according to one embodiment of the present invention;

FIG. 2 illustrates a perspective view of a heat sink according to one embodiment of the present invention;

FIG. 3 illustrates a perspective view of a heat sink according to one embodiment of the present invention;

FIG. 4 illustrates a schematic top view of a heat sink according to one embodiment of the present invention; and

FIG. 5 is a schematic side view of a thermal dissipation structure according to one embodiment of the present invention.

### DETAILED DESCRIPTION

The following embodiments are disclosed with accompanying diagrams for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations. Also, the same labels may be regarded as the corresponding components in the different drawings unless otherwise indicated. The drawings are drawn to clearly illustrate the connection between the various components in the embodiments, and are not intended to depict the actual sizes of the components.

In addition, terms used in the specification and the claims generally have the usual meaning as each terms are used in the field, in the context of the invention and in the context of the particular content unless particularly specified. Some terms used to describe the invention are to be discussed below or elsewhere in the specification to provide additional guidance related to the description of the invention to specialists in the art.

The phrases “first,” “second,” etc., are solely used to separate the descriptions of elements or operations with the same technical terms, and are not intended to convey a meaning of order or to limit the invention.

Additionally, the phrases “comprising,” “includes,” “provided,” and the like, are all open-ended terms, i.e., meaning including but not limited to.

Further, as used herein, “a” and “the” can generally refer to one or more unless the context particularly specifies otherwise. It will be further understood that the phrases “comprising,” “includes,” “provided,” and the like used herein indicate the stated characterization, region, integer, step, operation, element and/or component, and does not exclude additional one or more other characterizations, regions, integers, steps, operations, elements, components and/or groups thereof.

For a drop cooling system, the dielectric coolant used for heat dissipation drips into the system to be cooled through the holes above the system. The dielectric coolant flows through the surface of the heating element or the heat sink. The heat generated by the element in the system to be cooled will be sensible heat or latent heat, and the sensible heat or latent heat is taken away from the system through the dielectric coolant. For the overall system to be cooled, the dielectric coolant has a net flow in a specific collecting direction. However, by observing the droplets flowing on a surface of the heat sink, it can be found that droplets of the dielectric coolant flow around with the drop position as the center and without a specific flow direction.

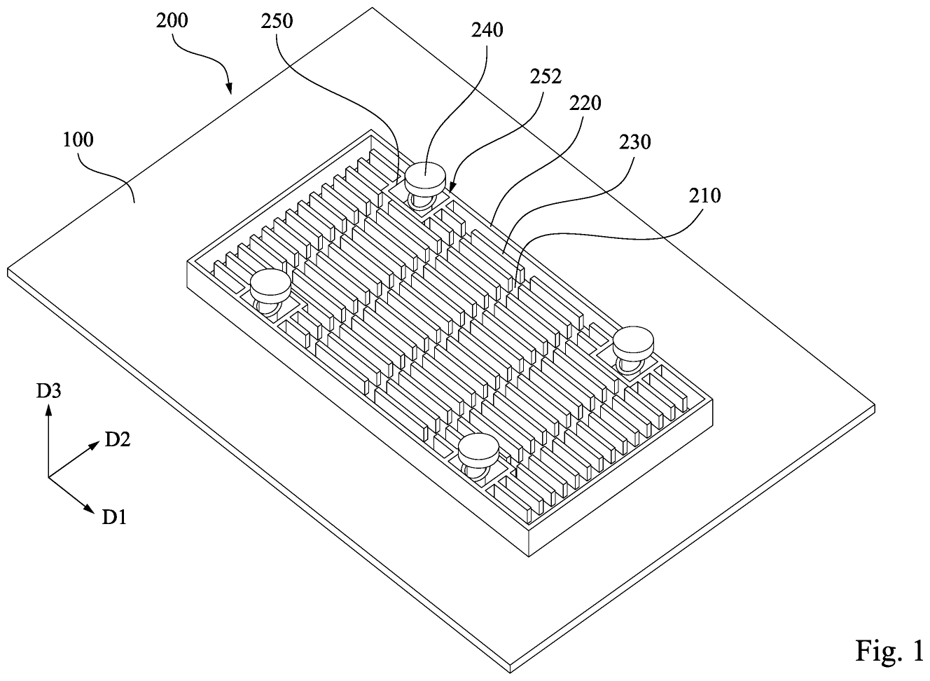

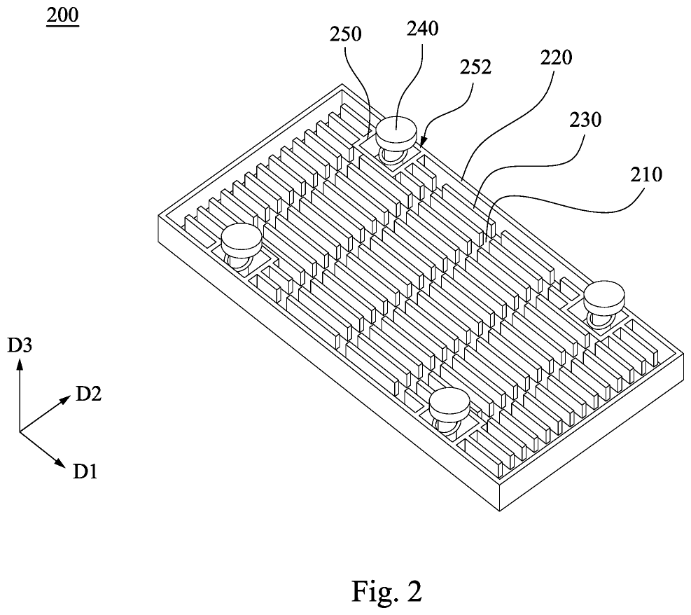

Reference is made by FIGS. 1 and 2. FIG. 1 illustrates a perspective view of a heat sink 200 located on a heat source 100 according to one embodiment of the present invention. FIG. 2 illustrates a perspective view of a heat sink 200 according to one embodiment of the present invention.

In one embodiment of the present invention, the heat sink 200 is used in a drop cooling system. The heat sink 200 can be located on a heat source 100, which is a system to be cooled. When the heat source 100 generates heat, the heat generated by the heat source 100 is conducted to the heat sink 200. Subsequently, the coolant is poured onto the heat sink 200 from a direction D3. After the dielectric coolant flows on the heat sink 200, the heat received by the heat sink 200 can be transferred to the dielectric coolant. Then, the dielectric coolant has a phase changing such that the heat is taken away.

In some embodiments of the present invention, the heat source 100, which is a system to be cooled, can be a component part of a computer or a server host. For the purpose of simple description, only one surface of the heat source 100 on which the heat sink 200 is illustrated in FIG. 1. In one embodiment of the present invention, the server host of the present invention can be used for artificial intelligence (AI) computing, edge computing, and can also be used as a 5G server, cloud server or used by the Internet of Vehicles server.

As shown in FIGS. 1 and 2, in some embodiments of the present invention, the heat sink 200 includes a bottom plate 210 and a liquid barrier structure 220. The bottom plate 210 includes material with good thermal conductivity such as metal. The bottom plate 210 is connected to the heat source 100 to receive heat generated by the heat source 100. The liquid barrier structure 220 is arranged on the periphery of the bottom plate 210 to prevent the coolant for heat dissipation from flowing out of the heat sink 200. In some embodiments of the present invention, the liquid barrier structure 220 is an enclosure provided on the periphery of the bottom plate 210 so that the coolant can be accumulated inside the liquid barrier structure 220.

In some embodiments of the present invention, the coolant includes a dielectric fluid with poor electrical conductivity, so as to prevent unexpected current from flowing to the heat sink 200.

In FIGS. 1 and 2, the heat sink 200 has a locking structure 240 to fix the heat sink 200 on the heat source 100. In this embodiment, the four locking structures 240 are adjacent to the edge of the bottom plate 210, which means that the four locking structures 240 are respectively arranged adjacent to the liquid barrier structure 220. The heat sink 200 further includes an isolation wall 250 surrounding the locking structure 240 and isolation walls 250 and the liquid barrier structure 220 can form an isolation chamber 252 containing the locking structure 240. Therefore, the locking structure 240 in the isolation chamber 252 can be isolated from the coolant dripping onto the heat sink 200, and the coolant do not escape from the locking structure 240.

As shown in FIGS. 1 and 2, in this embodiment, the heat sink 200 further includes a plurality of sheet-shaped heat conducting fin 230. The heat conducting fin 230 are long strips, and the heat conducting fins 230 extend along the direction D1. The sheet-shaped heat conducting fins 230 are arranged at equal intervals from each other in the direction D1 and are parallel to each other in the direction D2.

The sheet-shaped heat conducting fins 230 are used to increase the heat dissipation area. When the heat sink 200 receives the heat conducted by the heat source 100, the heat can be further conducted to the heat conducting fins. In some embodiments of the present invention, the material of the sheet-shaped heat conducting fins 230 includes metal with good thermal conductivity.

Regarding to the heat conducting fins 230 shown in FIGS. 1 and 2, the droplets of coolant dripping onto the heat sink 200 can flow in the direction D1 between the heat conducting fins 230.

The coolant droplets can also take away the heat transferred to the heat conducting fins 230. Through the spacing/section grooves between the heat conducting fins 230, the coolant droplets can flow in the directions D1 and D2 to a certain extent until they reach one side of the liquid barrier structure 220.

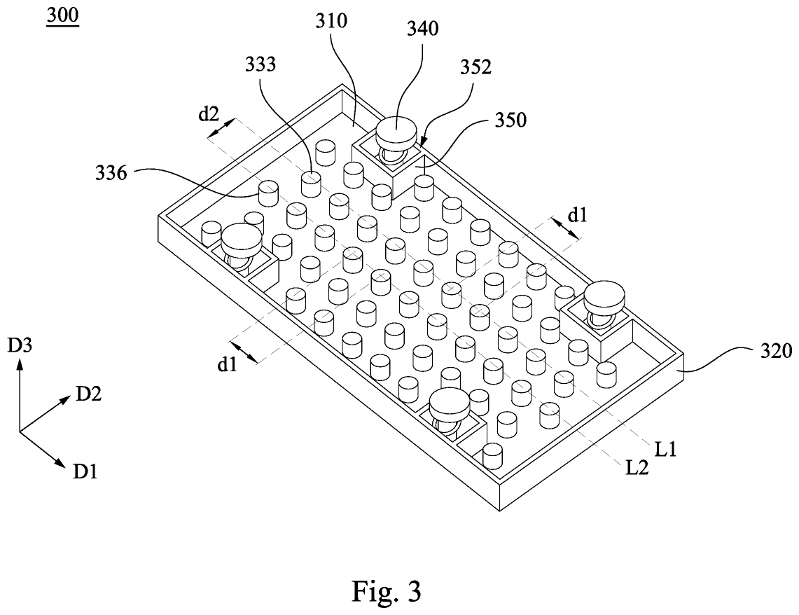

FIG. 3 illustrates a perspective view of a heat sink 300 according to one embodiment of the present invention.

In this embodiment, the heat sink 300 includes a bottom plate 310, a liquid barrier structure 320, and a plurality of columnar heat conducting fins 330. The liquid barrier structure 320 is located on the periphery of the bottom plate 210. The columnar heat conducting fins 330 are located on the bottom plate 310, and the columnar heat conducting fins 330 are located in the liquid barrier structure 320.

The heat sink 300 further includes a locking structure 340 on the bottom plate 310 for fixing with the heat source 100. In FIG. 3, the locking structure 340 is located at the edge of the heat sink 300 and is surrounded by the isolation wall 350 and the liquid barrier structure 320. The isolation walls 350 and the liquid barrier structure 320 jointly surround the locking structures 340. In other words, the isolation walls 350 and the liquid barrier structure 320 form an isolation chamber 352 for accommodating the locking structure 340 to ensure that the coolant accumulated by the heat sink 300 do not flow to the locking structure 340 and escape from the gap of the locking structure 340.

Compared with the fin 230 of the heat sink 200 in FIG. 2, the columnar heat sink fins 330 of the heat sink 300 in FIG. 3 are cylindrical, which facilitates the flow of coolant drops on the bottom plate 310.

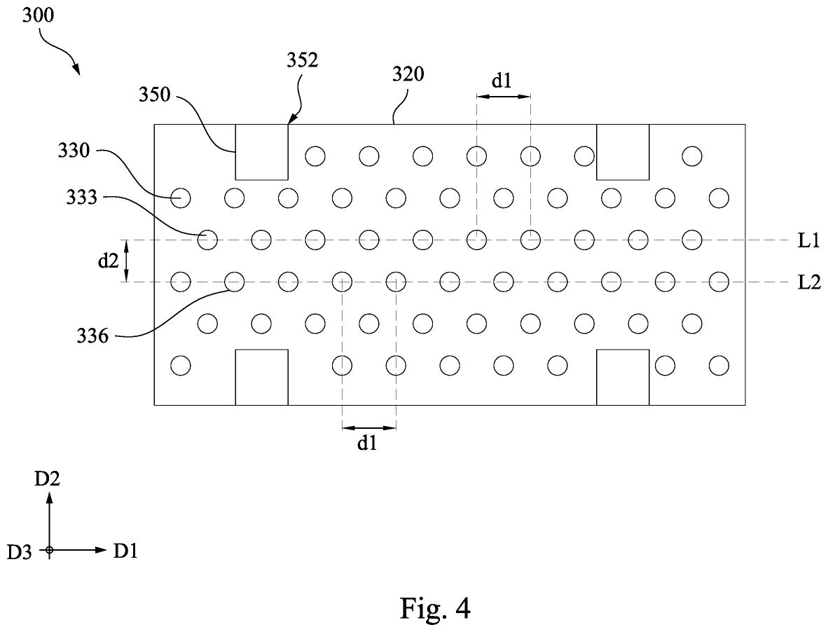

Reference is made by FIGS. 3 and 4. FIG. 4 illustrates a schematic top view of a heat sink 300 according to one embodiment of the present invention. For the purpose of simple description, FIG. 4 does not illustrate the locking structure 340 of the heat sink 300.

As shown in FIG. 4, projections of columnar heat conducting fins 330 of the heat sink 300 on the bottom plate 310 is a circle. In this embodiment, the direction D1 and the direction D2 are perpendicular to each other. Since the coolant droplets received by the heat sink 300 can move on the bottom plate 310 of the heat sink 300 in the directions D1 and D2, when the coolant droplets contact the columnar heat conducting fins 330, the smooth curved surfaces of the columnar heat conducting fins 330 have low flow resistance for the coolant droplet. The influence of the columnar heat conducting fins 330 on the flow velocity of the coolant drops can be reduced.

In some embodiments of the present invention, projection shapes of the columnar heat conducting fins 330 on the bottom plate 310 can include a perfect circle or an ellipse. In some embodiments, the projections of each of the columnar heat conducting fin is elliptical such that the length of the columnar heat conducting fin 330 in the direction D1 and the direction D2 is different. For example, in some embodiments and similar to the heat conducting fin 230 of the heat sink 200 in FIG. 2, the length of the columnar heat conducting fin 330 in the direction D1 is greater than the length of the columnar heat conducting fin 330 in the direction D2, and the columnar heat conducting fin 330 can guide the coolant droplets to move in the direction D1. The elliptical columnar heat conducting fins 330 can have lower flow resistance and reduce the influence of the coolant droplets on the heat sink 300.

On the other hand, as shown in FIGS. 3 and 4, on the heat sink 300, the columnar heat conducting fins 330 are arranged in a staggered manner, which can disperse the coolant droplets on the heat sink 300. It avoids the occurrence of local evaporation of the coolant droplets on the surface of the bottom plate 310 of the heat sink 300, which can cause damage to the components caused by local hot spots.

Specifically, in this embodiment, the columnar heat conducting fins 330 are arranged at intervals with the same interval d1 in the direction D1. As shown in FIGS. 3 and 4, the columnar heat conducting fins 330 are arranged in a plurality of straight rows in the direction D1. The straight rows extend in the direction D1. The straight are arranged in the direction D2 and parallel to each other. The two immediately-adjacent ones of the straight rows are spaced apart at the same interval d2. The straight rows include a first straight row L1 and a second straight row L2, which are to immediately-adjacent straight rows. The first straight rows L1 and the second straight row L2 are separated by the same interval d2, and the first straight rows L1 and the second straight row L2 are substantially offset from each other in the direction D2.

For example, first columnar heat conducting fins 333 are located on the first straight row L1, and a second columnar heat conducting fins 336 are located on the second straight row L2. Since the first straight row L1 and the second straight row L2 are misaligned with each other in the direction D2, any of the first columnar heat conducting fins 333 cannot be aligned with any of the second columnar heat conducting fins 336 in the direction D2. This corresponds to that any of the first columnar heat conducting fins 333 and any of the second columnar heat conducting fins 336 in the direction D2 cannot be aligned and are not opposite to each other. Therefore, the columnar heat conducting fins 330 can play a role in guiding the coolant to flow uniformly on the bottom plate 310, thereby increasing the temperature uniformity and heat dissipation effect of the heat sink 300.

In summary, on the heat sink 300, columnar heat conducting fins 330 are provided, and the columnar heat conducting fins 330 are arranged alternately on the bottom plate 310 of the heat sink 300. The design of the cylindrical columnar heat conducting fins 330 can reduce the flow resistance of the coolant, and the staggered arrangement of the columnar heat conducting fins 330 can improve the temperature uniformity of the heat sink 300 and increase the heat dissipation capacity of the heat sink 300. The liquid barrier structure 320 on the bottom plate 310 of the heat sink 300 can prevent the coolant from escaping from the heat sink 300.

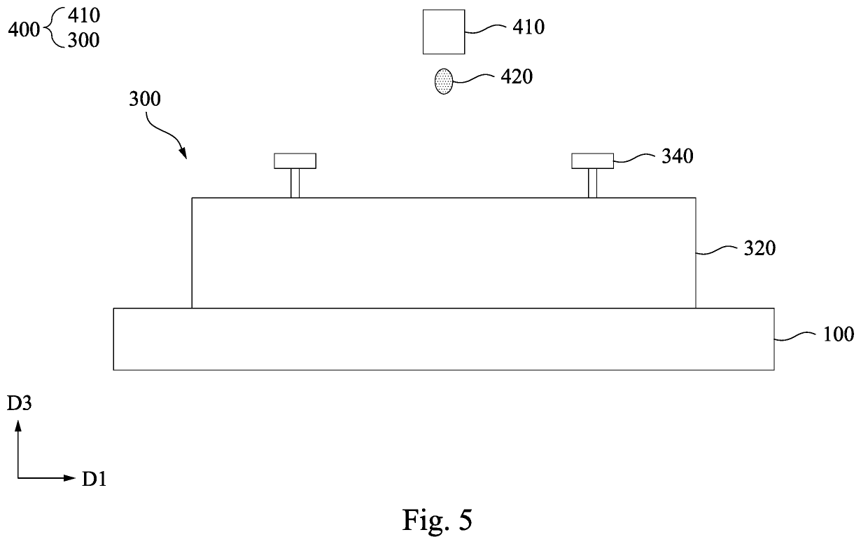

FIG. 5 is a schematic side view of a thermal dissipation structure 400 according to one embodiment of the present invention. As shown in FIG. 5, the thermal dissipation structure 400 is used to dissipate the heat source 100. The thermal dissipation structure 400 includes a heat sink 300 and a coolant source 410. The heat sink 300 is fixed on the heat source 100 by the locking structure 340. In the direction D3, the coolant source 410 is arranged above the heat sink 300 so as to drip the coolant droplet 420 onto the heat sink 300.

Therefore, once the heat source 100 generates heat, the coolant source 410 located above the heat sink 300 drips the coolant droplet 420 toward the heat sink 300. The coolant droplet 420 is received by the heat sink 300 and is confined within the liquid barrier structure 320 of the heat sink 300 without escaping. The heat source 100 is conducted to the heat sink 300 and its columnar heat sink fins 330 (as shown in FIGS. 3 and 4). The coolant droplets 420 can be evenly distributed on the heat sink 300 through the staggered columnar heat conducting fins 330. The cylindrical columnar heat conducting fins 330 reduce the flow resistance of the coolant droplets 420 on the heat sink 300 and make it easier for the coolant droplets 420 to carry heat at different positions on the heat sink 300.

In one embodiment of the present invention, the system to be cooled can be a server, and the server of the present invention can be used for artificial intelligence (AI). In some embodiments, the server can also be used as a 5G server, a cloud server, or a server for Internet of Vehicles.

Although the present invention has been described in considerable detail with reference to certain embodiments thereof, other embodiments are possible. Therefore, the spirit and scope of the appended claims should not be limited to the description of the embodiments contained herein. In view of the foregoing, it is intended that the present invention cover modifications and variations of this invention provided they fall within the scope of the following claims.

What is claimed is:

1. A heat sink, comprising:
a bottom plate;
a liquid barrier structure located on a periphery of the bottom plate; and
a plurality of heat conducting fins arranged on the bottom plate, wherein the heat conducting fins are located in the liquid barrier structure.

2. The heat sink of claim 1, wherein the heat conducting fins comprise a plurality of columnar heat conducting fins.

3. The heat sink of claim 2, wherein a projection of each of the columnar heat conducting fins on the bottom plate is a circle.

4. The heat sink of claim 3, wherein the columnar heat conducting fins are arranged in a plurality of straight rows in the liquid barrier structure, the straight rows extend in a first direction, and the straight rows are arranged in a second direction.

5. The heat sink of claim 4, wherein the first direction is perpendicular to the second direction.

6. The heat sink of claim 5, wherein the columnar heat conducting fins are arranged at equal intervals in the first direction.

7. The heat sink of claim 6, wherein the straight rows comprise a first straight row and a second straight row that are immediately-adjacent two of the straight rows, a plurality of first columnar heat conducting fins of the columnar heat conducting fins are arranged in the first straight row, a plurality of second columnar heat conducting fins of the columnar heat conducting fins are arranged in the second straight row, and any one of the first columnar heat conducting fins is not aligned with any of the second columnar heat conducting fins in the second direction.

8. The heat sink of claim 1, further comprising:
a locking structure arranged on the bottom plate; and
an isolation wall located on the bottom plate, wherein the isolation wall is arranged between the locking structure and the heat conducting fins.

9. The heat sink of claim 8, wherein the locking structure is adjacent to the periphery of the bottom plate, the isolation wall is connected to the liquid barrier structure, and the isolation wall and the liquid barrier structure jointly surround the locking structure.

10. A thermal dissipation structure, comprising:
a heat sink arranged on a heat source, wherein the heat sink comprises:
a bottom plate;
a liquid barrier structure located on a periphery of the bottom plate; and
a plurality of columnar heat conducting fins arranged on the bottom plate, wherein the columnar heat conducting fins are located in the liquid barrier structure; and
a coolant source arranged above the heat sink to drip a coolant on the columnar heat conducting fins, wherein the coolant source drips the coolant toward the liquid barrier structure.
